(19) United States
(12) Patent Application Publication
(10) Pub. No.: US 2026/0073100 A1
(43) Pub. Date: Mar. 12, 2026

(54) CROP SPECIES IDENTIFICATION SYSTEM BASED ON SATELLITE TELEMETRY DATA

(71) Applicants: CHUN-HSIAO WU, Taipei City (TW); DATAYOO APPLICATION CO., LTD., Taipei City (TW)

(72) Inventors: CHUN-HSIAO WU, Taipei City (TW); CHING-WEN YANG, Taipei City (TW)

(21) Appl. No.: 19/325,123

(22) Filed: Sep. 10, 2025

(30) Foreign Application Priority Data
Sep. 10, 2024 (TW) 113134308

(51) Int. Cl. G06F 30/27; G06N 3/0464

(52) U.S. Cl. CPC G06F 30/27; G06N 3/0464

(57) ABSTRACT

A crop species identification system based on satellite telemetry data is disclosed, which includes: a receiver module, receiving plural telemetric vegetation indexes of a target area; a data cleaning module, cleaning anomalous data in the telemetric vegetation indices, to correspondingly generate cleaned index data; a feature extraction module, including at least two different convolution kernels for mapping the cleaned index data into at least two feature scale mapping data which respectively correspond to the convolution kernels, performing a pooling operation of the feature scale mapping data to generate a pooled data, and concatenating the at least two feature scale mapping data and the pooled data into concatenated data; and a classification module, including a fully-connected layer, for extracting features of the concatenated data, to generate a species classification result for the target area.

### CROSS-REFERENCE TO RELATED APPLICATIONS

This application claims priority to Taiwan Invention patent application No. 113134308, filed on Sep. 10, 2024, the entire disclosure of which is hereby incorporated by reference.

### BACKGROUND OF THE INVENTION

### 1. Field of the Invention

The present invention provides a crop species identification technology, particularly a technology configured to perform crop species identification through the analysis of long-term sequential remote sensing data.

### 2. Description of the Prior Art

Long-term sequential satellite telemetry data analysis and prediction are critical technologies in smart agriculture and plant growth forecasting. Such long-term sequential data are generally composed of satellite telemetry data combined in chronological order, and are characterized by high complexity, making the required analysis of long-term sequential data particularly challenging. Furthermore, the telemetry data received from satellites often contain noise or missing values, which must be properly processed; otherwise, they may result in excessive deviation in the analytical outcomes.

### SUMMARY OF THE INVENTION

To satisfy the requirements of long-term sequential satellite telemetry data and the processing of noise or missing values in the telemetry data, the present invention provides a crop species identification system based on satellite telemetry data. The system comprises: a receiver module configured to receive a telemetric vegetation index of a target area; a data cleaning module configured to process anomalous data in the telemetric vegetation index to generate cleaned index data; a feature extraction module having at least two different convolution kernels configured to perform mapping operations on the cleaned index data to respectively generate at least two feature scale mapping data corresponding to the convolution kernels, wherein the feature extraction module performs pooling operations on the feature scale mapping data to generate pooled data, and concatenates the at least two feature scale mapping data and the pooled data to generate concatenated data; and a classification module including a fully-connected layer configured to extract features from the concatenated data to generate a species classification result of the target area. Signal connections are established among the receiver module, the data cleaning module, the feature extraction module, and the classification module.

In one embodiment, a satellite performs telemetry on a region to generate the telemetric vegetation index corresponding to the target area. The telemetric vegetation index includes Biomass, Water content, or temperature. In one embodiment, the Biomass includes the Normalized difference red edge (NDRE), the Normalized difference vegetation index (NDVI), or the Normalized difference water index (NDWI).

In one embodiment, the anomalous data in the telemetric vegetation index include missing values, duplicate values, and noisy values. The index preprocessing comprises estimating the missing values by linear interpolation, smoothing the noisy values using a moving average method, or eliminating the duplicate values.

In one embodiment, the at least two convolution kernels include a 1×1 convolution kernel, a 3×3 convolution kernel, and a 5×5 convolution kernel. The pooling layer is a max pooling layer, wherein the max pooling size is 3×3. In one embodiment, the feature extraction module of the present invention

comprises: an input layer configured to receive the cleaned index data; at least two convolutional layers, each having corresponding convolution kernels, wherein each convolutional layer performs a mapping operation on the cleaned index data using its respective convolution kernel to generate at least two feature scale mapping data corresponding to the convolution kernels; and a pooling layer configured to perform a pooling operation on the feature scale mapping data based on a representative value selection principle to generate corresponding pooled data.

In one embodiment, the representative value selection principle of the pooling layer includes a maximum value principle or an average value principle. The pooling layer may be a max pooling layer that generates the pooled data according to the maximum value principle, or an average pooling layer that generates the pooled data according to the average value principle.

In one embodiment, the fully-connected layer forms the aforementioned convolutional neural network (CNN), in which the neurons are interconnected. The convolutional neural network generates the species classification result based on the concatenated data.

In one embodiment, the classification module further includes a dropout layer, wherein the dropout layer deactivates a portion of the neurons in the convolutional neural network. The deactivated neurons do not transmit information, thereby reducing the problem caused by overfitting and improving the accuracy of the species classification result determined by the crop species identification system based on satellite telemetry data.

In one embodiment, the receiver module, the data cleaning module, the feature extraction module, and the classification module may be disposed in a controller of at least one of the following: a satellite, a ground station, a terminal device communicatively connected to the satellite, or a terminal device communicatively connected to the ground station.

In one embodiment, the feature extraction module further includes a self-attention mechanism, which evaluates the similarity among data at different time points within the long-term sequential telemetric vegetation index to generate an attention output (value). The attention output (value) is produced through the query and key in the self-attention mechanism. The attention output enhances the classification capability of the feature extraction module with respect to the species classification result.

In one embodiment, the species classification result includes crop type, crop species distribution, or crop species quantity.

In one embodiment, the crop species identification system based on satellite telemetry data further comprises a model training module connected to the classification module. The model training module includes an adaptive moment estimation function and a categorical cross entropy function, thereby enhancing the computational capability for the species classification result.

According to one aspect, the present invention further provides a crop species identification method based on satellite telemetry data, comprising: receiving a telemetric vegetation index of a target area; processing anomalous data in the telemetric vegetation index through index preprocessing to generate cleaned index data; performing mapping operations on the cleaned index data using at least two different convolution kernels to respectively generate at least two feature scale mapping data corresponding to the convolution kernels; performing a pooling operation on the feature scale mapping data to generate pooled data, and concatenating the at least two feature scale mapping data and the pooled data to generate concatenated data; and forming a fully-connected layer to extract features from the concatenated data, thereby generating a species classification result of the target area.

The aforementioned types of data may be represented in various forms, including scalars, vectors, tensors, or matrices.

### BRIEF DESCRIPTION OF THE DRAWINGS

FIG. 1 illustrates a schematic diagram of the crop species identification system based on satellite telemetry data according to one embodiment of the present invention.

FIG. 2 illustrates a schematic diagram of satellite telemetry of the Earth's surface according to one embodiment of the present invention.

FIG. 3 illustrates a schematic diagram of the feature extraction module according to one embodiment of the present invention.

FIG. 4 illustrates a schematic diagram of the convolutional neural network according to two embodiments of the present invention.

FIG. 5 illustrates a schematic diagram of the classification module according to one embodiment of the present invention.

FIG. 6 illustrates a schematic diagram of neuron deactivation in the convolutional neural network according to one embodiment of the present invention.

FIG. 7 illustrates a schematic diagram of the model training module connected to the classification module according to one embodiment of the present invention.

FIG. 8 illustrates a flow schematic diagram of the crop species identification method based on satellite telemetry data according to one embodiment of the present invention.

### DETAILED DESCRIPTION OF THE PREFERRED EMBODIMENTS

The aforementioned and other technical contents, features, and advantages of the present invention will be clearly presented in the following detailed description of the preferred embodiments with reference to the accompanying drawings.

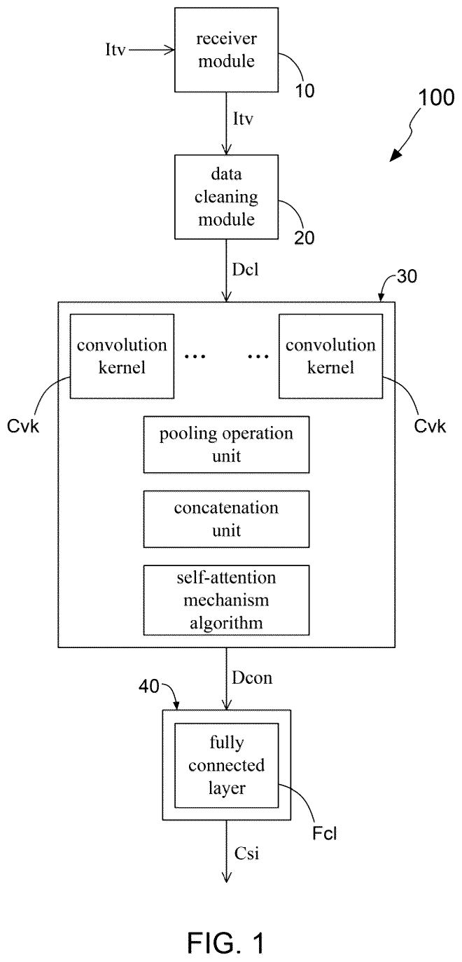

Referring to FIG. 1, with respect to the aforementioned technical requirements, the present invention provides a crop species identification system based on satellite telemetry data 100, which comprises: a receiver module 10, configured to receive a telemetric vegetation index Itv of a target area; a data cleaning module 20, configured to process anomalous values in the telemetric vegetation index Itv to generate preprocessed data Dcl; a feature extraction module 30, having at least two different convolution kernels Cvk, wherein the feature extraction module 30 performs mapping operations on the preprocessed data Dcl using the convolution kernels Cvk to generate at least two feature scale data corresponding to the convolution kernels Cvk, performs pooling operations on the feature scale data to generate pooled data, and concatenates (Concatenate) the at least two feature scale data and the pooled data to generate concatenated data Dcon; and a classification module 40, comprising a fully connected layer (Fully Connected Layer, Fcl), wherein the fully connected layer Fcl extracts features from the concatenated data Dcon to generate a species classification result Csi for the target area. As shown in the figure, the receiver module 10, the data cleaning module 20, the feature extraction module 30, and the classification module 40 are signal-connected. The data cleaning module 20 provides various methods to clean the received telemetric vegetation index Itv (as described in subsequent embodiments) to ensure that the preprocessed data Del after cleaning is suitable for subsequent processing steps. The feature extraction module 30 has the function of feature extraction and further performs dimensionality reduction to improve computational efficiency.

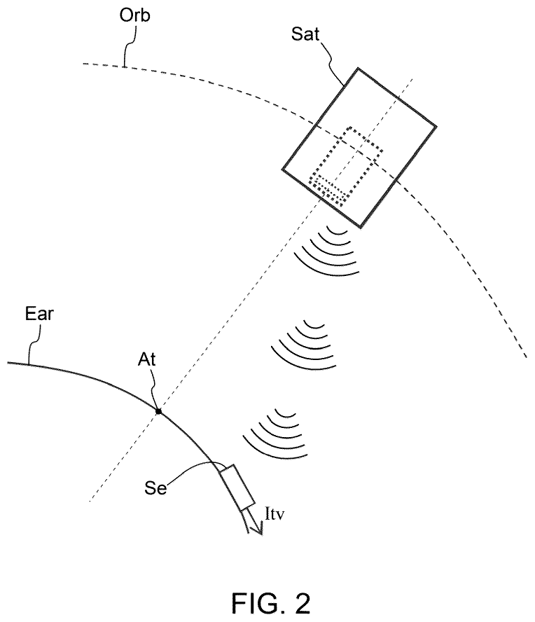

Referring to FIG. 2, in one embodiment, a satellite Sat operating in an orbit Orb performs telemetry on a target area At of the Earth's surface Ear. A ground station Se receives wireless information from the satellite to generate the telemetric vegetation index Itv corresponding to the target area At. The telemetric vegetation index Itv includes Biomass, Water content, or temperature. In one embodiment, the Biomass includes the Normalized difference red edge (NDRE), the Normalized difference vegetation index (NDVI), or the Normalized difference water index (NDWI). These telemetric vegetation indices Itv are mainly generated by the satellite Sat through optical telemetry.

In one embodiment, the anomalous values in the telemetric vegetation index Itv include missing values, duplicate values, and noisy values. The index preprocessing includes estimating missing values by linear interpolation, smoothing noisy values by moving average, or eliminating duplicate values. In the original telemetric vegetation index Itv, noise or irregular fluctuations may exist, such as anomalous values caused by poor weather conditions leading to variations in vegetation indices. The invention cleans missing values and smooths noisy values to ensure that the data is in a state suitable for subsequent steps, thereby avoiding abnormal determinations in the species classification result Csi caused by anomalous values. The linear interpolation method can fill these missing values, making the long time-series data more continuous and complete. The moving average method can smooth these fluctuations, providing more stable and reliable long time-series data.

In one embodiment, the at least two convolution kernels Cvk include a 1×1 convolution kernel, a 3×3 convolution kernel, and a 5×5 convolution kernel.

The pooling layer 33L is a max pooling layer, where the max pooling size is 3×3. Convolution kernels Cvk of different sizes can map the preprocessed data Dcl to generate feature data of different scales. According to the operations of different convolution kernels Cvk, the preprocessed data Dcl is respectively mapped into the corresponding feature data of each convolution kernel Cvk. Smaller convolution kernels may capture weekly or monthly variations of the telemetric vegetation index Itv, while larger convolution kernels may capture seasonal or annual patterns of the telemetric vegetation index Itv. In addition, the invention can utilize the translation invariance of one-dimensional convolution to handle growth cycle differences that may arise from planting practices or crop varieties in different regions, thereby enhancing the stability of model prediction. Furthermore, convolution operations can also act as filters to help suppress high-frequency noise in satellite data, such as reducing the influence of atmospheric interference, cloud cover, and other factors that cause deviations in the values of the telemetric vegetation index Itv. Subsequently, feature data of different scales and pooled data are concatenated into concatenated data Dcon.

The aforementioned max pooling layer can effectively extract and preserve important features across different time scales. For example, during the crop growth process, certain key growth stages (such as the flowering stage) may be reflected as local maximum values of the index. The max pooling size can also be adjusted as needed.

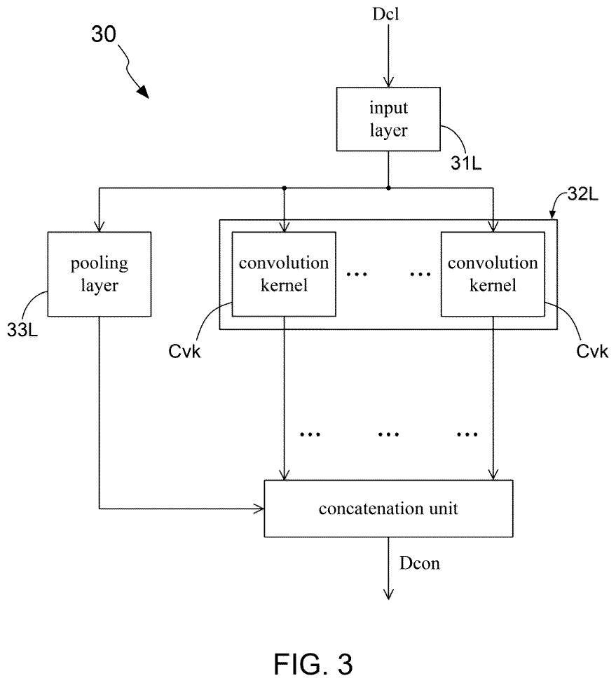

Referring to FIG. 3, in one embodiment, the feature extraction module 30 of the present invention includes: an input layer 31L, configured to receive the preprocessed data Dcl; at least two convolutional layers 32L, each having corresponding convolution kernels Cvk, wherein each convolutional layer 32L performs mapping operations on the preprocessed data Del according to the corresponding convolution kernel Cvk, respectively generating at least two feature scale data corresponding to the convolution kernels Cvk (thereby capturing both short-term variations and long-term trends of vegetation indices, and through concatenation, integrating multiple feature vectors so that the model can learn features by incorporating vegetation index variations across different time scales, such as weeks, months, seasons, and years); and a pooling layer 33L, which performs pooling operations on the feature scale data according to a representative value selection principle to generate corresponding pooled data. The max pooling layer, in particular, can emphasize seasonal variation patterns over larger time scales, reduce the spatial dimensions of feature maps while preserving important feature information, and lower computational costs.

In one embodiment, the representative value selection principle in the pooling layer 33L includes the maximum value principle or the average value principle. When the pooling layer 33L is a max pooling layer, pooled data corresponding to the max pooling layer is generated according to the maximum value principle. Alternatively, when the pooling layer 33L is an average pooling layer, pooled data corresponding to the average pooling layer is generated according to the average value principle.

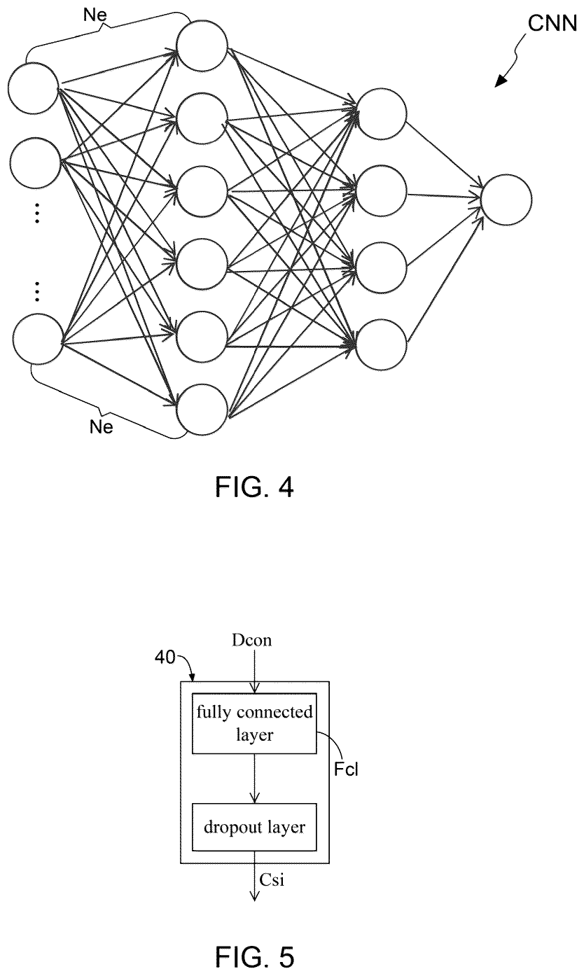

Referring to FIG. 4, in one embodiment, the fully connected layer Fcl generates the aforementioned convolutional neural network (Convolutional Neural Network, CNN), in which the neurons Ne within the convolutional neural network CNN are interconnected. The convolutional neural network CNN generates the species classification result based on the concatenated data. The number and distribution of the neurons Ne, as well as the signal connections (straight lines with arrows) between the neurons Ne, are merely illustrative, and the convolutional neural network CNN can be designed as required by the user according to implementation needs.

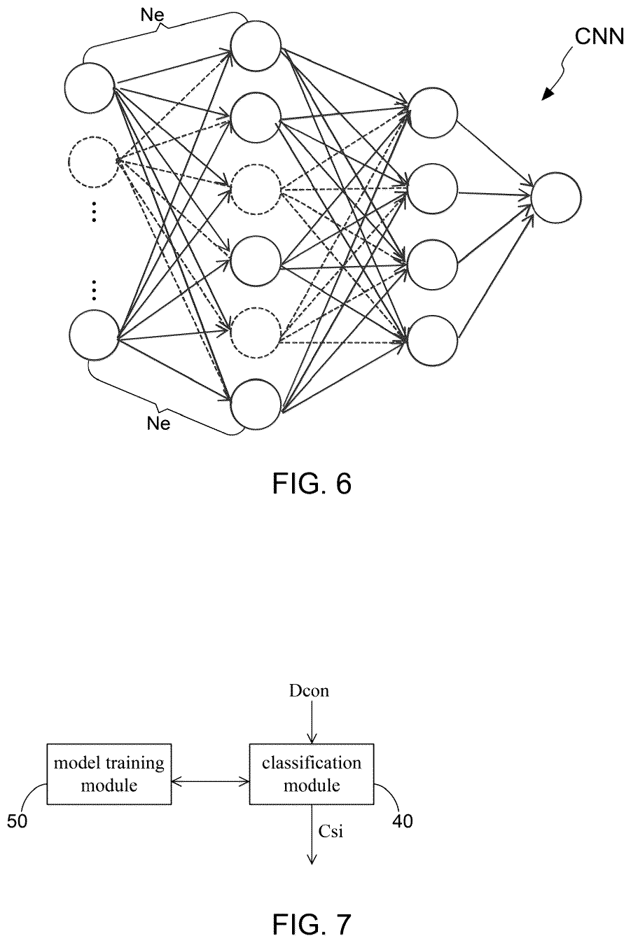

Referring to FIG. 5, in one embodiment, the classification module 40 further includes a dropout layer 41L (Dropout Layer). In the dropout layer 41L, a portion of the neurons Ne in the convolutional neural network CNN cease operation (see FIG. 6, where dashed lines illustrate neurons Ne stopping operation and signal connections not transmitting information), in order to reduce issues caused by overfitting (Over fitting) and to improve the accuracy of the crop species identification system 100 in determining the species classification result Csi. In addition, by ceasing the operation of certain neurons Ne, the convolutional neural network CNN may have adjustable flexibility, generating different possible computational model combinations, which can be regarded as a model that integrates multiple potential network structures. The dropout layer 41L provides a regularization method against overfitting, in which during training, at each iteration (epoch), hidden layer neurons Ne are discarded with a certain probability.

In one embodiment, the receiver module 10, the preprocessing module 20, the feature extraction module 30, and the classification module 40 may be disposed within at least one controller selected from a satellite Sat, a ground station Se, a terminal device connected to the satellite Sat, or a terminal device connected to the ground station Se. In one embodiment, the aforementioned controller may include: a Central Processing Unit (CPU), a Neural network Processing Unit (NPU), a Tensor Processing Unit (TPU), a Micro Control Unit (MCU), a Programmable Logic Controller (PLC), an Instruction Set Architecture (ISA) processor, a Microprocessor, an Application Specific Integrated Circuit (ASIC), a Digital Signal Processor (DSP), an Arithmetic Logic Unit (ALU), a Graphics Processing Unit (GPU), an Image Signal Processor (ISP), a Complex Programmable Logic Device (CPLD), a Field Programmable Gate Array (FPGA), or other similar components and combinations thereof. In another embodiment, the controller may further include a device or circuit that executes stored program codes, such as a Network Interface Controller (NIC), among others.

Referring to FIG. 1, in one embodiment, the feature extraction module 30 further includes a self-attention mechanism (Self-Attention Mechanism). For the long time-series preprocessed data Dcl (or, alternatively, the long time-series telemetric vegetation index Itv), the similarity among data points at different time intervals is used to generate an attention output (Value). Through queries (Query) and keys (Key) in the self-attention mechanism, the attention output (Value) is generated. The attention output enhances the classification capability of the feature extraction module 30 for the species classification result Csi. Based on the requirement of convolutional neural network CNN operations for time-series data fusion, the CNN is combined with the self-attention mechanism algorithm to improve the feature capture capability for long time-series data. The self-attention mechanism algorithm can calculate correlations within the entire time-series data (for example, the vegetation index variations of a crop during the growing season this year may exhibit a pattern similar to that of the same crop during the growing season last year). By applying queries (Query) and keys (Key), the attention output (Value) is generated to establish correlations among vegetation index variations of related crops. In this way, the attention output can determine relevant data within the long time-series dataset. In one embodiment, the queries, keys, and attention outputs are represented in vector form, namely as query vectors, key vectors, and attention output vectors. The similarity between a query vector and a key vector is generally measured by inner product computation. These similarity values can then be transformed into attention weights using the Softmax function, where the weights indicate the importance of each element relative to the others. These attention weights can be applied to perform a weighted summation of the attention output vectors.

In one embodiment, the species classification result Csi includes crop types, crop species distribution, or crop species quantity. In another embodiment, the technology of the present invention may also be applied to generate species classification results Csi such as surface vegetation types, surface vegetation species distribution, or surface vegetation species quantity.

In one embodiment, the crop species identification system 100 further includes a model training module 50, wherein the model training module 50 is connected to the classification module 40 (see FIG. 7). The model training module 50 comprises an Adaptive Moment Estimation function and a Categorical Cross Entropy function to enhance the computational capability of the species classification result Csi. The Adaptive Moment Estimation function combines gradients from the computational data to adjust the learning rate of each computational parameter. Its key characteristics include employing the concept of momentum to accelerate the gradient descent of computational data and maintaining consistency in the update direction to facilitate faster convergence of computational results. In addition, Adaptive Moment Estimation can adjust the learning rate based on the first-order and second-order moment estimates of each computational parameter. The Categorical Cross Entropy function uses a loss function to quantify the difference between the generated species classification result Csi and the actual reference values, thereby improving the reliability of the generated species classification result Csi.

In this application, the Categorical Cross Entropy function is based on the following formula:

$${\sum }_{C = 1}^{L} {\sum }_{i = 1}^{N} [ - {y}_{c , i} log ( {\hat{y}}_{c , i} ) ]$$

Where c denotes that the model predicts across L different crop species, i represents the i-th sample among the N time-series data, and y_{c,i} is the true crop label output, indicating whether the prediction result yᵢ corresponds to crop c (equal to 1 if true, and 0 if false). ŷ_{c,i} represents the output of the “model-predicted crop label,” that is, the probability that the model predicts yᵢ as belonging to crop c, with a value range of [0,1]. By minimizing the categorical cross entropy, the model ensures that during the training process, the loss function is directly optimized and iteratively updated for the final crop identification task.

The technology proposed in this invention belongs to a deep learning time-series classification model. By introducing information extraction techniques for time-series data such as convolution kernels and attention mechanisms, the proposed technology demonstrates clear novelty in extracting crop features from remote sensing data and achieves higher accuracy and robustness in crop identification. Specifically:
1. Deep learning algorithms can automatically learn complex patterns in time-series data and have better processing capabilities for nonlinear and multidimensional data. Compared with traditional mathematical methods such as the maximum curvature method, they can significantly improve the efficiency and accuracy of extracting crop information from remote sensing data.
2. A convolution kernel is usually a small learnable parameter matrix that slides along the time series and focuses only on a small portion of the sequence (similar to a time window). This allows the model to learn local feature structures and patterns in the time series (such as specific frequencies or shapes), without the need to consider all details of the entire sequence.
3. Multiple convolution kernels of different sizes and quantities can be configured to form convolutional layers, which can capture features at different scales and levels of complexity. This feature extraction approach helps in understanding patterns across different time scales, thereby improving the performance and generalization capability of the classification model.
4. The attention mechanism can automatically learn the importance weights of the convolution kernels based on the input time-series data, enabling the model to focus more on critical convolution kernel features and more accurately identify key patterns in the time series. In crop identification using remote sensing data, where crop growth patterns and agricultural operation differences are complex, the proposed model can significantly enhance the accuracy and robustness of the classification results.
5. The invention achieves satellite-based species identification through a deep learning model for time-series classification. During the model training phase, the loss function is minimized, where this loss function is derived from the categorical cross entropy between the “model-predicted crop label” and the “true crop label.” By minimizing categorical cross entropy, the method ensures that during model training, the loss function is directly optimized and iteratively updated for species identification. In contrast, traditional time-series variational models use a loss function that is only effective for simulating time series, and additional parameters such as phenological period days and threshold comparisons of remote sensing vegetation indices must be incorporated during crop identification. The introduction of such thresholds may cause additional errors, preventing the loss function from directly optimizing the final prediction task. Compared with traditional techniques, the proposed method provides innovation and improves overall prediction performance and reliability of results.

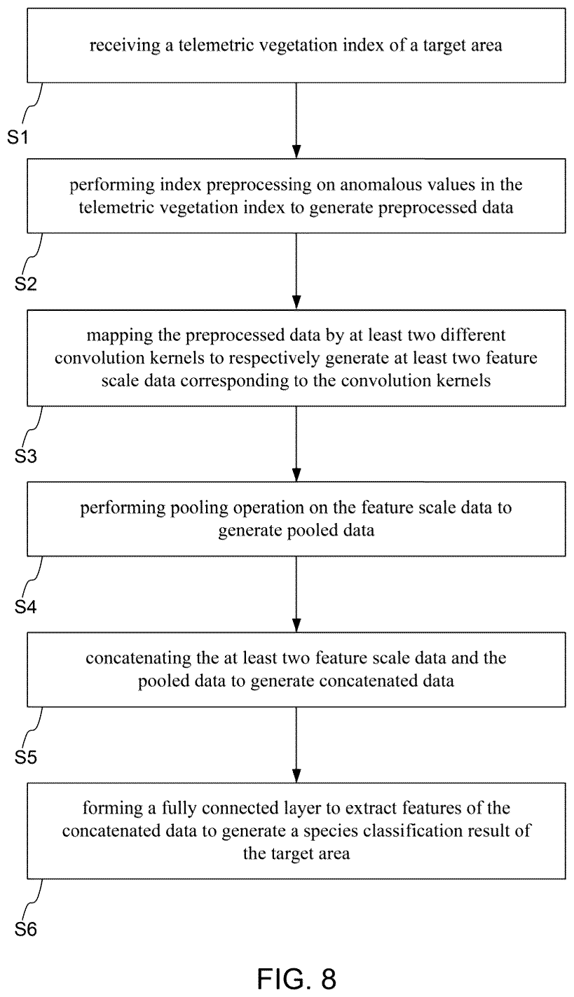

Referring to FIG. 8, in another aspect, the invention further provides a satellite-based species identification method, comprising: receiving a telemetric vegetation index of a target area (S1); performing index preprocessing on anomalous values in the telemetric vegetation index to generate preprocessed data (S2); mapping the preprocessed data by at least two different convolution kernels to respectively generate at least two feature scale data corresponding to the convolution kernels (S3), performing pooling operation on the feature scale data to generate pooled data (S4), and concatenating the at least two feature scale data and the pooled data to generate concatenated data (S5); and forming a fully connected layer to extract features of the concatenated data Dcon in the fully connected layer, so as to generate a species classification result of the target area (S6). Explanations of the respective steps can be found in the foregoing embodiments.

The foregoing description has been given with reference to preferred embodiments of the present invention. However, the above description is merely for enabling those skilled in the art to readily understand the content of the invention, and is not intended to limit the scope of rights or the disclosed technology of the invention. Any person skilled in the art may, without departing from the scope of the technical solution of the present application, make combinations, minor modifications, or alterations based on the disclosed technical content to form equivalent embodiments.

What is claimed is:

1. A crop species identification system based on satellite telemetry data, comprising:
a receiver module, configured to receive a telemetric vegetation index of a target area;
a preprocessing module, configured to perform index preprocessing on anomalous values in the telemetric vegetation index so as to generate preprocessed data;
a feature extraction module, including at least two different convolution kernels, configured to map the preprocessed data by the convolution kernels to respectively generate at least two feature scale data corresponding to the convolution kernels, the feature extraction module being further configured to perform pooling operation on the feature scale data to generate pooled data, and to concatenate the at least two feature scale data and the pooled data to generate concatenated data; and
a classification module, including a fully connected layer, configured to extract features of the concatenated data in the fully connected layer to generate a species classification result of the target area;
wherein the receiver module, the preprocessing module, the feature extraction module, and the classification module are signal-connected with each other.

2. The crop species identification system based on satellite telemetry data according to claim 1, wherein a satellite performs telemetry on a region to generate the telemetric vegetation index corresponding to the region, and the telemetric vegetation index includes biomass, water content, or temperature.

3. The crop species identification system based on satellite telemetry data according to claim 2, wherein the biomass includes a normalized difference red edge (NDRE), a normalized difference vegetation index (NDVI), or a normalized difference water index (NDWI).

4. The crop species identification system based on satellite telemetry data according to claim 1, wherein the anomalous data in the telemetric vegetation index includes missing values, duplicate values, and noise values, and the index preprocessing includes estimating the missing values by a linear interpolation method, smoothing the noise values by a moving average method, or eliminating the duplicate values.

5. The crop species identification system based on satellite telemetry data according to claim 1, wherein the at least two convolution kernels include a 1×1 convolution kernel, a 3×3 convolution kernel, and a 5×5 convolution kernel, and the pooling layer is a max pooling layer, wherein the max pooling size is 3×3.

6. The crop species identification system based on satellite telemetry data according to claim 1, wherein the feature extraction module comprises:
an input layer, configured to receive the pre-processed data;
at least two convolution layers, each convolution layer respectively comprising a corresponding convolution kernel, each convolution layer performing a mapping operation on the pre-processed data according to the corresponding convolution kernel to generate at least two feature scale data corresponding to the convolution kernels; and
a pooling layer, configured to perform a pooling operation on the feature scale data based on a representative value selection principle to generate corresponding pooled data.

7. The crop species identification system based on satellite telemetry data according to claim 6, wherein the representative value selection principle in the pooling layer comprises a maximum value principle or an average value principle, wherein when the pooling layer is a maximum pooling layer, the pooled data is generated according to the maximum value principle; or when the pooling layer is an average pooling layer, the pooled data is generated according to the average value principle.

8. The crop species identification system based on satellite telemetry data according to claim 1, wherein the fully connected layer generates a convolutional neural network, in which a plurality of neurons are interconnected, and the convolutional neural network generates the species classification result based on the concatenated data.

9. The crop species identification system based on satellite telemetry data according to claim 8, wherein the classification module further comprises a dropout layer, in which the dropout layer deactivates a portion of the neurons in the convolutional neural network to improve the accuracy of the crop species identification system in determining the species classification result.

10. The crop species identification system based on satellite telemetry data according to claim 1, wherein the receiver module, the preprocessing module, the feature extraction module, and the fully connected layer are disposed in at least one controller of a satellite, a ground station, a terminal device connected to the satellite, or a terminal device connected to the ground station.

11. The crop species identification system based on satellite telemetry data according to claim 1, wherein the feature extraction module further comprises a self-attention mechanism, which generates an attention output (Value) based on the similarity among data at different time points of a long-term sequence of the telemetric vegetation index, and the attention output enhances the computational efficiency of the feature extraction module for the species classification result.

12. The crop species identification system based on satellite telemetry data according to claim 1, wherein the species classification result comprises crop type, crop species distribution, or crop species quantity.

13. The crop species identification system based on satellite telemetry data according to claim 1, further comprising a model training module connected to the classification module, wherein the model training module comprises an adaptive moment estimation function and a categorical cross entropy function, to improve the computational efficiency of the species classification result.

14. A crop species identification method based on satellite telemetry data, comprising:
receiving a telemetric vegetation index of a target area;
performing an index preprocessing on anomalous values in the telemetric vegetation index to generate preprocessed data;
mapping the preprocessed data through at least two different convolution kernels to respectively generate at least two scale feature data corresponding to the convolution kernels, performing a pooling operation on the scale feature data to generate pooled data, and concatenating the at least two scale feature data and the pooled data to generate concatenated data; and
forming a fully connected layer, wherein the fully connected layer extracts features of the concatenated data to generate a species classification result for the target area.
